(19) United States
(12) Patent Application Publication
(10) Pub. No.: US 2004/0099879 A1
(43) Pub. Date: May 27, 2004

(54) Heterojunction bipolar transistor power transistor

(75) Inventors: Yung Jinn Chen, Kaohsiung (TW); Yu Chi Wang, Taoyuan City (TW); Tsung-Chi Tsai, Taipei (TW); Shih-Ming Joseph Liu, Taipei (TW)

Correspondence Address: BACON & THOMAS, PLLC, 625 SLATERS LANE, FOURTH FLOOR, ALEXANDRIA, VA, 22314

(73) Assignee: WIN SEMICONDUCTORS CORP., Tao Yuan Shien (TW)

(21) Appl. No.: 10/304,689

(22) Filed: Nov. 27, 2002

(51) Int. Cl. H01L 31/0328

(52) U.S. Cl. 257/183

(57) ABSTRACT

A heterojunction bipolar transistor (HBT) power transistor with improved ruggedness is disclosed. The optimized design of HBT power transistor combines the use of ballasting resistors, coupling capacitors, as well as novel layout of the transistor cell, which avoids the problem of thermal runaway while maintaining the performance of the HBT power transistor.

### FIELD OF THE INVENTION

The present invention relates to an optimized design of heterojunction bipolar transistor (HBT) power transistor having improved ruggedness, more particularly, relates to an optimized design of HBT power transistor by combining the use of ballasting resistors and novel layout of the transistor cell, which can avoid the thermal runaway while maintaining the performance of the HBT power transistor.

### BACKGROUND OF THE INVENTION

Power amplifier is the most important component in the transmitter of a cellular telephone, or other wireless communication systems. A common power amplifier consists of many unit transistors, wherein each unit transistor commonly utilizes the Heterojunction Bipolar Transistor (HBT). For an HBT power transistor, there exist a so-called “self-heating” problem, which will result in thermal runway and destructing of the device operation. The self-heating effect is originated from the positive-feedback relationship between the collector current and the temperature of the transistor, which leads the transistor to be thermally unstable. As can be expected from the current-temperature relationship of a pn junction, higher temperature leads to an increased collector current, which in turn heats up the transistor and hence further increasing the collector current. This unstable condition could rapidly destruct the operation of a power transistor, or even damage the device permanently.

In order to avoid the problem of thermal runway and improve the device ruggedness, ballasting resistors were commonly included in the emitter of an HBT. When the collector current increases, the emitter-ballasting resistor (EBR) will increase the emitter voltage and reduce the voltage drop between the base and the emitter, and hence decreasing the collector current. In other words, the EBR can effectively avoid the self-heating problem by forming a negative-feedback loop between input and output. However, the use of EBR still has some drawbacks. For example, if the resistance of the EBR is too large, the power gain of the HBT device will be undesirably reduced under RF operations and therefore reducing the efficiency of the power amplifier.

An alternative way to ballast the HBT device is the use of base-ballasting resistor (BBR) instead of the EBR. The BBR connected in series with the input signal not only can prevent premature current collapse but also stabilize the RF signal at the cost of reduced power gain and therefore PAE. This disadvantage can be eliminated by shunting the BBR in the DC path with a RF coupling capacitor in the signal path. Therefore, the power transistor ruggedness can be preserved without sacrificing the gain and efficiency.

Besides the use of ballasting resistor, the thermal runaway can also be avoided by optimizing the cell design of an HBT power transistor in transistor level rather than in circuit level. A conventional HBT power transistor usually contains a plurality of emitter fingers. However, if the arrangement of these emitter fingers and base contacts contains some “sharp corners”, the current spreading in these emitter fingers will be non-uniform. This non-uniform current spreading will locally heat up the region of higher current density, then in turn further increase the current density in this region, and finally destroy the operation of the power transistor. Therefore, to avoid the non-uniform temperature distribution, the arrangement of these emitter fingers and base contacts on the base mesa is also an important issue.

### SUMMARY OF THE INVENTION

The object of the present invention is to explore the optimized design of an HBT power transistor with improved ruggedness, so that the problem of thermal runaway can be avoided while maintaining the device performance. The scheme adopted in the present invention for improving the ruggedness of HBT device includes not only the optimization of transistor cell design in circuit level by using ballasting resistors, but also in transistor level by disposing a novel layout of the HBT power transistor cell.

A feature of the layout of the HBT power transistor cell is the arrangement of emitter fingers and base contacts on the base mesa, wherein the possibility of sharp-corner effect has been excluded, so that the current spreading in emitter finger will be evenly distributed and the effects of non-uniform temperature distribution can be greatly reduced.

Another feature of the invention is the use of a coupling capacitor shunted with the base-ballasting resistor, which can prevent the premature current collapse of and improve the device performance of the HBT power transistor.

### BRIEF DESCRIPTION OF DRAWINGS

FIG. 1 is a top view of a layout of a conventional HBT power transistor.

FIG. 2 is a top view of a layout of an HBT power transistor configured in accordance with the first preferred embodiment of the present invention.

FIG. 3 is a top view of a layout of an HBT power transistor including a base-ballasting resistor, an emitter-ballasting resistor, and a coupling capacitor, which are configured in accordance with the second preferred embodiment of the present invention.

FIG. 4 is a top view of a layout of an multi-finger HBT power transistor including a base-ballasting resistor, an emitter-ballasting resistor, and a coupling capacitor, which are configured in accordance with the third preferred embodiment of the present invention.

FIG. 5 is a top view of a layout of an HBT power transistor including a base-ballasting resistor, an emitter-ballasting resistor, and a coupling capacitor, which are configured in accordance with the fourth preferred embodiment of the present invention.

FIGS. 6A and 6B show the device performance of Design A and B respectively.

FIGS. 7A and 7B illustrate the collector current-voltage characteristics (I_{C}-V_{C}) of Design C and D respectively.

### DETAILED DESCRIPTION OF PREFERRED EMBODIMENTS

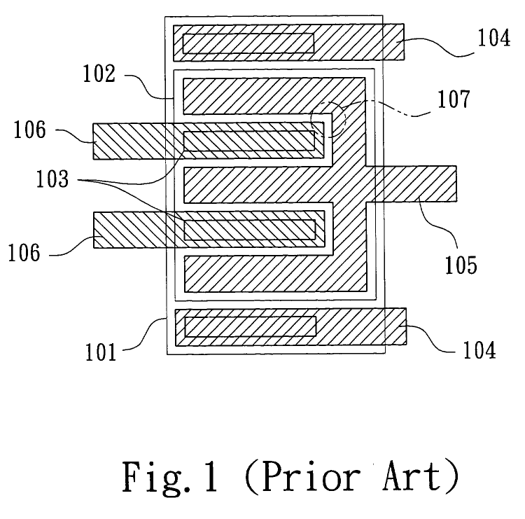

FIG. 1 illustrates a layout of a conventional HBT cell design of prior art. It generally comprises three regions: a collector region 101, a base region 102 and an emitter region 103. The collector region 101 includes two rectangular collector contacts 104 and a rectangular base region 102 (also referred as a base mesa). The base mesa 102 includes base contact fingers 105 and two rectangular emitter regions 103 exterior to the base contact fingers 105. Emitter contacts fingers 106 are deposited over the emitters regions 103 and are electrically isolated from the base region 102. It is worth to note that the arrangement of these emitter contact fingers 106 and base contact fingers 105 contains some “sharp corners”, as highlighted by a circle 107 in FIG. 1. The emitter current drawn from the collector contacts 104 around the sharp corner region will be non-uniform. This non-uniform emitter current spreading will locally heat up the region of higher current density, then in turn further increase the current density in this region, and finally destroy the operation of the power transistor.

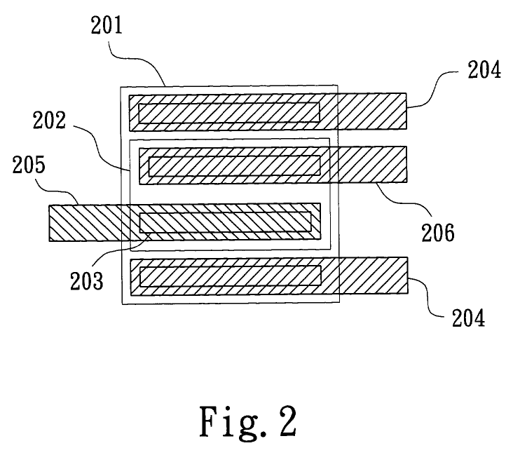

FIG. 2 illustrates a more compact layout of an HBT cell without sharp corner effects, which is also a first preferred embodiment of the presented invention. It generally comprises three regions: a collector region 201, a base region 202 and an emitter region 203. The collector region 201 includes two collector contacts 204 and a rectangular base mesa forming the base region 202. The base mesa 202 includes a rectangular base contact 205 and a rectangular emitter region 203 close to the base contact 205. An emitter contact 206 is deposited on the emitter region 203 and is electrically isolated from the base region 202. As can be seen in this figure, this arrangement avoids the possibility of sharp-corner effects, and the device ruggedness can be improved.

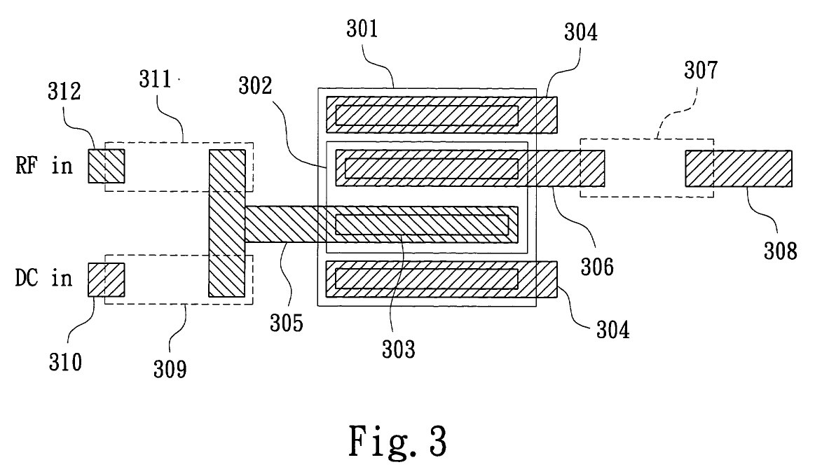

As shown in FIG. 3, the HBT cell with compact layout as described in FIG. 2 can further include a base ballasting resistor, an emitter-ballasting resistor, and/or a coupling capacitor shunted with the base-ballasting resistor, which is also a second preferred embodiment of the present invention. The same as the first preferred embodiment, the HBT cell comprises three regions: a collector region 301, a base region 302 and an emitter region 303. The collector region 301 includes two collector contacts 304 and a rectangular base mesa 302. The base mesa 302 includes a rectangular base contact 305 and a rectangular emitter region 303 and a rectangular emitter contact 306 deposited thereon. An emitter ballast resistor 307 is coupled between the emitter contact 306 and an emitter terminal 308. A base ballast resistor 309 is coupled between the base contact 305 and a base terminal 310 for DC bias input. A coupling capacitor 311 shunted with the base-ballasting resistor 309 is coupled between the base contact 305 and a coupling capacitor terminal 312 for RF input.

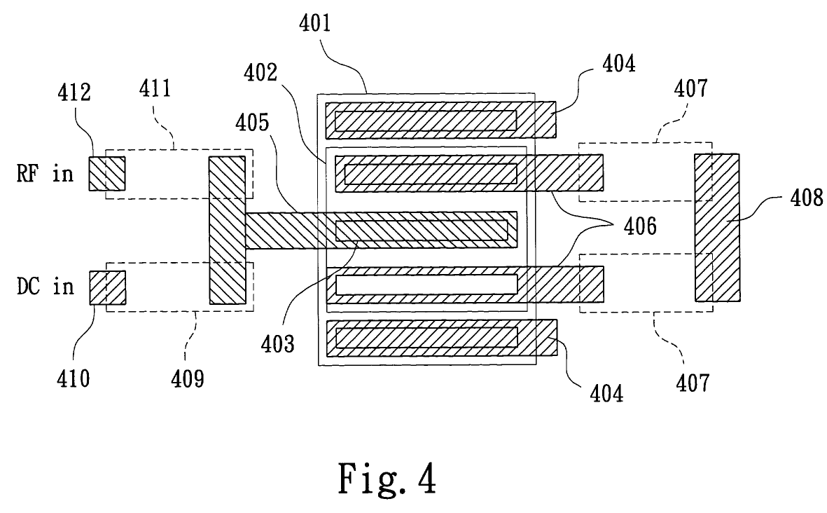

Base on the compact layout described in FIG. 2, the HBT cell can also be designed as a multi-finger device. FIG. 4 is a third preferred embodiment of the present invention, in which the HBT layout is designed as a multi-finger device. Similar to the second preferred embodiment, the multi-finger HBT device shown in FIG. 4 also comprises a collector region 401, a base region 402 and an emitter region 403. The collector region 401 includes two collector contacts 404 and a rectangular base mesa 402. The base mesa 402 includes a rectangular base contact 405 and two rectangular emitter regions 403 disposed at both side of the base contact 405. Each emitter region 403 is deposited by an emitter contact finger 406 and is electrically isolated from the base region 402. Each emitter contact 406 is coupled to an emitter ballast resistor 407 and then coupled to an emitter terminal 408. A base-ballasting resistor 409 is coupled between the base contact 405 and a base terminal 410 for DC bias input. A coupling capacitor 411 shunted with the base-ballasting resistor 409 is coupled between the base contact 405 and a coupling capacitor terminal 412 for RF input.

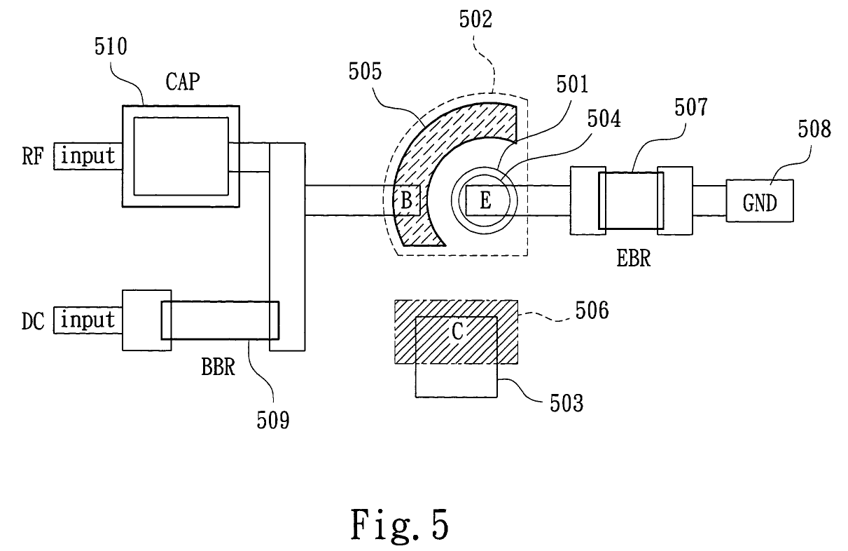

The shapes of emitter and base contact electrodes are obviously not limited to the rectangular shape. The contact electrodes can be designed to be any shape, as long as the configuration of these contact fingers excludes the possibility of sharp corners. FIG. 5 illustrates one possible scheme contains a circular emitter region 501 on a base mesa 502, while the shape of outer collector region 503 and the collector contact 506 thereon remain rectangular. A circular shaped emitter contact 504 is deposited on the emitter region 501. The emitter contact can be further connected to an emitter-ballasting resistor 507, whereto an emitter terminal 508 is connected. A general circular form base contact 505 is disposed around the circular emitter contact 504 on the base mesa 502. The base contact is further connected to a base-ballasting resistor 509 for DC input and to a shunt coupling capacitor 510 for RF input.

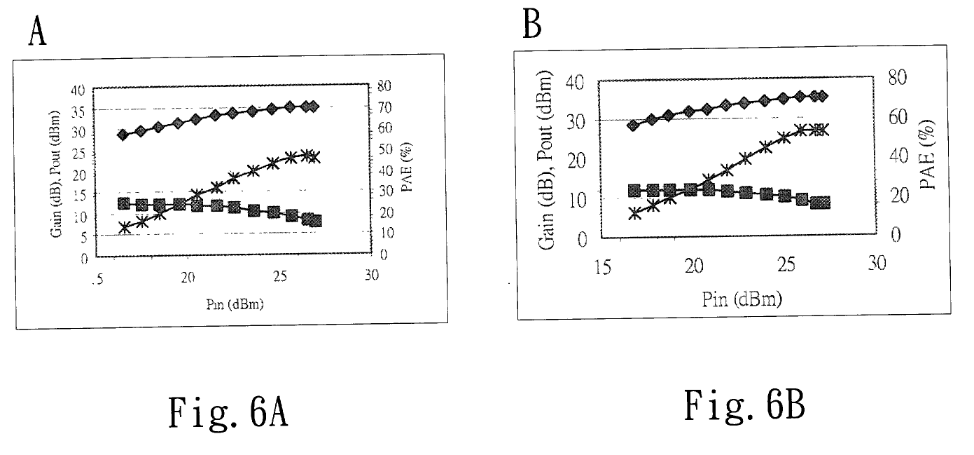

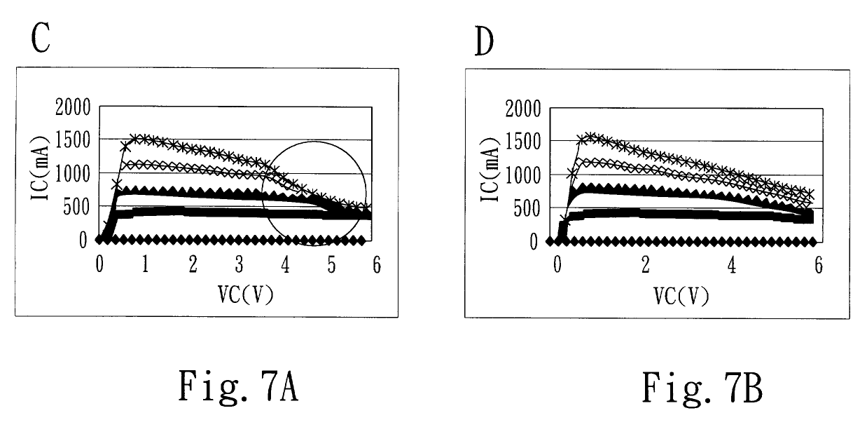

FIGS. 6A and 6B show the device performance of two different designs (Design A and B). The total emitter area of these two designs is 7680 μm², and both device use 3-Ω emitter-ballasting resistor and 100-ω base-ballasting resistor in series with their base contact. The main difference in these two device is their transistor layout: Design A uses the layout of prior arts as depicted in FIG. 1, while Design B uses the layout of the second preferred embodiment of the present invention. In FIG. 6, the device performance of these two designs are compared. The power amplify efficiency (PAE) of Design B shows nearly 10% higher than that of the Design A, even though both designs have identical emitter—and base-ballasting resistors. From our ruggedness test, the Design A can only pass 10:1 VSWR at V_{CE}=4 V, (collector-emitter voltage), while the Design B passed 10:1 VSWR at V_{CE}=5 V. In FIGS. 7A and 7B show the collector current-voltage characteristics (I_{C}-V_{C}) of another two designs (Design C and D), which will illustrates unambiguously how a improved device performance can be achieved by carefully optimizing ballasting resistors and shunt coupling capacitor. In Design C, it uses a 3-Ω emitter-ballasting resistor and a 75-Ω base-ballasting resistor in series with the base contact without any coupling capacitor. For the Design D, it uses a 125-Ω base-ballasting resistor in shunt with a 1.3 pF coupling capacitor, without using any emitter-ballasting resistor. As shown in FIG. 7, premature current collapse is found in Design C for V_{C}>4 V. Moreover, the Design D typically shows PAE ˜10% higher than the Design C, due to the use of shunted base-ballasting resistor and without using emitter-ballasting resistor. Furthermore, we also found that Design D is more thermally stable as compared to Design C. Our ruggedness test shows that Design C failed at VCE=3.6 V for 8:1 VSWR, while the Design D passed 10:1 VSWR at V_{CE}>5V. From these comparative analysis, we conclude that better performance and ruggedness can be achieved simultaneously by applying appropriate ballasting resistor design and unit cell design.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An heterojunction bipolar transistor (HBT) power transistor, comprising: a collector region, a base region and an emitter region, said base region being disposed on said collector region in form of a base mesa, and said emitter region being included in said base mesa;
two rectangular collector contacts disposed on the collector region;
a rectangular base contact disposed on the base mesa; and
a rectangular emitter contact deposited on the emitter region, said rectangular emitter contact electrode being electrically isolated from the base region, and having a long edge facing to one of the long edges of the rectangular base contact.

2. An HBT power transistor as describe in claim 1, wherein the base contact is further electrically connected to a base ballasting resistor.

3. An HBT power transistor as describe in claim 1, wherein the emitter contact is further electrically connected to an emitter ballasting resistor.

4. An HBT power transistor as describe in claim 1, wherein the base contact is further electrically connected to a base ballasting resistor and a shunt coupling capacitor.

5. An HBT power transistor as describe in claim 1, wherein the base contact is further electrically connected to a base ballasting resistor; and the emitter contact is further electrically connected to an emitter ballasting resistor.

6. An HBT power transistor as describe in claim 1, wherein the base contact is further electrically connected to a base ballasting resistor and a shunt coupling capacitor; and the emitter contact is further electrically connected to an emitter ballasting resistor.

7. An heterojunction bipolar transistor (HBT) power transistor, comprising:
a collector region, a base region and an emitter region, said base region being disposed on said collector region in form of a base mesa, and said emitter region being included in said base mesa;
two rectangular collector contacts disposed on the collector region;
a rectangular base contact disposed on the base mesa; and
two rectangular emitter contacts deposited at both sides of the rectangular base contact on the emitter region, each of said rectangular emitter contact electrode being electrically isolated from the base region, and having a long edge facing to one of the long edges of the rectangular base contact.

8. An HBT power transistor as describe in claim 7, wherein the base contact is further electrically connected to a base ballasting resistor.

9. An HBT power transistor as describe in claim 7, wherein each emitter contact is further electrically connected to an emitter ballasting resistor.

10. An HBT power transistor as describe in claim 7, wherein the base contact is further electrically connected to a base ballasting resistor and a shunt coupling capacitor.

11. An HBT power transistor as describe in claim 7, wherein the base contact is further electrically connected to a base ballasting resistor; and each emitter contact is further electrically connected to an emitter ballasting resistor.

12. An HBT power transistor as describe in claim 7, wherein the base contact is further electrically connected to a base ballasting resistor and a shunt coupling capacitor; and each emitter contact is further electrically connected to an emitter ballasting resistor.

13. An heterojunction bipolar transistor (HBT) power transistor, comprising:
a collector region, a base region and an emitter region, said base region being disposed on said collector region in form of a base mesa, and said emitter region being included in said base mesa;
a rectangular collector contact disposed on the collector region;
a circular emitter contact disposed on the base mesa; and
a circular form base contact deposited around the circular emitter contact on the base region, said circular emitter contact electrode being electrically isolated from the base region, and the curvatures of the emitter and base contacts are designed so that the current is drawn radically and evenly to the emitter.

14. An HBT power transistor as describe in claim 13, wherein the base contact is further electrically connected to a base ballasting resistor.

15. An HBT power transistor as describe in claim 13, wherein each emitter contact is further electrically connected to an emitter ballasting resistor.

16. An HBT power transistor as describe in claim 13, wherein the base contact is further electrically connected to a base ballasting resistor and a shunt coupling capacitor.

17. An HBT power transistor as describe in claim 13, wherein the base contact is further electrically connected to a base-ballasting resistor; and each emitter contact is further electrically connected to an emitter-ballasting resistor.

18. An HBT power transistor as describe in claim 13, wherein the base contact is further electrically connected to a base ballasting resistor and a shunt coupling capacitor; and each emitter contact is further electrically connected to an emitter ballasting resistor.
